(19) United States
(12) Patent Application Publication
(10) Pub. No.: US 2015/0382444 A1
(43) Pub. Date: Dec. 31, 2015

(54) THERMALLY ENHANCED WIRING BOARD HAVING METAL SLUG AND MOISTURE INHIBITING CAP INCORPORATED THEREIN AND METHOD OF MAKING THE SAME

(71) Applicant: BRIDGE SEMICONDUCTOR CORPORATION, Taipei (TW)

(72) Inventors: Charles W. C. Lin, Singapore (SG); Chia-Chung Wang, Hsinchu County (TW)

(21) Appl. No.: 14/846,984

(22) Filed: Sep. 7, 2015

Related U.S. Application Data
(63) Continuation-in-part of application No. 14/621,332, filed on Feb. 12, 2015.
(60) Provisional application No. 61/949,652, filed on Mar. 7, 2014.

(51) Int. Cl. H05K 1/02; H05K 3/44; H05K 1/18; H05K 3/40; H05K 3/16; H05K 3/28; H05K 3/18

(52) U.S. Cl. CPC H05K 1/0204; H05K 3/28; H05K 3/44; H05K 3/181; H05K 3/4046; H05K 3/16; H05K 1/181; H05K 2203/1327; H05K 2203/02; H05K 2203/1377; H05K 2201/09227; H05K 2201/10416; H05K 2201/10242

(57) ABSTRACT

A method of making a wiring board having a metal slug incorporated in a resin core is characterized by the provision of a moisture inhibiting cap covering interfaces between metal and plastic. In a preferred embodiment, the metal slug is bonded to the resin core by an adhesive substantially coplanar with the metal slug and the metal layers on two opposite sides of the resin core at smoothed lapped top and bottom surfaces so that a metal bridge can be deposited on the adhesive at the smoothed lapped bottom surface to completely cover interfaces between the metal slug and the surrounding plastic material. In the method, conductive traces are also deposited on the resin core at the smoothed lapped top surface so as to provide electrical contacts for chip connection.

### CROSS REFERENCE TO RELATED APPLICATIONS

This application is a continuation-in-part of U.S. application Ser. No. 14/621,332 filed Feb. 12, 2015, which claims benefit of U.S. Provisional Application Ser. No. 61/949,652 filed Mar. 7, 2014. Said applications are hereby incorporated by reference.

### FIELD OF THE INVENTION

The present invention relates to a wiring board, and more particularly to a thermally enhanced wiring board having a moisture inhibiting cap covering interfaces between a metal slug and a surrounding plastic material and a method of making the same.

### DESCRIPTION OF RELATED ART

Semiconductor devices are susceptible to performance degradation as well as short life span and may even suffer immediate failure at high operating temperatures. As such, when a semiconductor chip is assembled into a package, it often requires a thermally enhanced wiring board to provide effective heat dissipation so that the heat generated by the chip can flow to the ambient environment for a reliable operation.

A good and effective design of thermally enhanced wiring board typically includes a metal portion and a resin portion. The metal portion provides heat dissipation channel whereas the resin portion that allows the wiring circuitry to be deposited thereon provides electrical signal routing. However, due to the contact area of these two materials is small and fragile, and their coefficients of thermal expansion (CTE) are largely mismatched, the interface of metal/resin is prone to crack or delamination during thermal cycling, making this type of circuit board prohibitively unreliable for practical usage because large amount of moisture may leak through the cracked interfaces and damage the assembled chip.

### SUMMARY OF THE INVENTION

A primary objective of the present invention is to provide a wiring board having at least one moisture inhibiting cap covering interfaces between two CTE-mismatched materials so as to prevent passage of moisture through cracks at the interfaces caused by mismatched CTE, thereby improving the reliability of the semiconductor assembly.

Another objective of the present invention is to provide a wiring board having a metal slug embedded in a resin core so that the resin core provides a platform for conductive trace deposition thereon and the metal slug can serve as an optimal heat spreader, thereby improving thermal dissipation and ensuring reliable operation of the semiconductor assembly.

In accordance with the foregoing and other objectives, the present invention provides a wiring board having a metal slug, a resin core, at least one moisture inhibiting cap and conductive traces. The metal slug provides primary heat conduction for a semiconductor chip so that the heat generated by the chip can be conducted away. The resin core, which provides mechanical support for the metal slug, the moisture inhibiting cap and the conductive traces, covers and surrounds sidewalls of the metal slug and serves as a spacer between the conductive traces and the metal slug. The moisture inhibiting cap, which laterally extends from the metal slug to the resin core, seals interfaces between metal and plastic and serves as a moisture barrier to prevent passage of moisture through cracks at the interfaces. The conductive traces, which laterally extend on the resin core, provide electrical contacts for chip connection and signal transmission and electrical routing of the board.

In another aspect, the present invention provides a method of making a thermally enhanced wiring board, comprising the steps of: providing a metal slug having planar first and second sides in opposite first and second directions, respectively; providing metal posts each having planar first and second sides in the first and second directions, respectively; providing a stacking structure that includes first and second metal layers, a binding film disposed between the first and second metal layers, and a first aperture extending through the first metal layer, the binding film and the second metal layer, wherein the first and second metal layers each have a planar outer surface in the first and second directions, respectively; inserting the metal slug into the first aperture of the stacking structure leaving a gap between the stacking structure and the metal slug, and then curing the binding film to form a resin core that has a first side bonded to the first metal layer and an opposite second side bonded to the second metal layer, wherein the stacking structure is adhered to sidewalls of the metal slug by an adhesive squeezed out from the binding film into the gap between the stacking structure and the metal slug; removing an excess portion of the squeezed out adhesive, thereby the adhesive having opposite exposed surfaces substantially coplanar with the first and second sides of the metal slug and the outer surfaces of the first and second metal layers in the first and second directions; forming conductive traces that laterally extend on the second side of the resin core; and forming a first moisture inhibiting cap that laterally extends from the first side of the metal slug to the first metal layer on the resin core to completely cover the exposed adhesive from the first direction.

In yet another aspect, another method of making a thermally enhanced wiring board comprises the steps of: attaching a metal slug on a carrier film, wherein the metal slug has planar first and second sides in opposite first and second directions, respectively; depositing a plastic embedding compound that covers the metal slug and the carrier film; removing a portion of the plastic embedding compound to form a resin core that has a first side in the first direction and a second side substantially coplanar with the second side of the metal slug in the second direction, and detaching the carrier film therefrom; forming conductive traces that laterally extend on the second side of the resin core; and forming a first moisture inhibiting cap that completely covers interfaces between the metal slug and the resin core from the first direction.

Unless specifically indicated or using the term “then” between steps, or steps necessarily occurring in a certain order, the sequence of the above-mentioned steps is not limited to that set forth above and may be changed or reordered according to desired design.

The method of making a thermally enhanced wiring board according to the present invention has numerous advantages. For instance, depositing the moisture inhibiting cap to seal interfaces between metal and plastic can establish a moisture barrier so that the moisture inhibiting cap can prevent moisture through cracks at the interfaces from ambiance into the interior of the semiconductor assembly, thereby improving the reliability of the assembly. Binding the metal slug to the resin core can provide a plastic platform for electrical routing deposition and a thermal conduction plane for semiconductor device attachment, thereby ensuring effective heat dissipation and reliable operation of the assembly.

These and other features and advantages of the present invention will be further described and more readily apparent from the detailed description of the preferred embodiments which follows.

### BRIEF DESCRIPTION OF THE DRAWINGS

The following detailed description of the preferred embodiments of the present invention can best be understood when read in conjunction with the following drawings, in which:

FIG. 1 is a cross-sectional view of a metal slug in accordance with the first embodiment of the present invention;

FIG. 2 is a cross-sectional view of a stacking structure on a carrier film in accordance with the first embodiment of the present invention;

FIG. 3 is a cross-sectional view showing the metal slug of FIG. 1 is attached to the carrier film of FIG. 2 in accordance with the first embodiment of the present invention;

FIGS. 4 and 5 are cross-sectional and top perspective views, respectively, showing the stacking structure of FIG. 3 is subjected to a lamination process in accordance with the first embodiment of the present invention;

FIGS. 6 and 7 are cross-sectional and top perspective views, respectively, showing excess adhesive is removed from the structures of FIGS. 4 and 5 in accordance with the first embodiment of the present invention;

FIG. 8 is a cross-sectional view showing the carrier film is removed from the structure of FIG. 6 in accordance with the first embodiment of the present invention;;

FIGS. 9, 10 and 11 are cross-sectional, bottom and top perspective views, respectively, showing the structure of FIG. 8 is provided with moisture inhibiting caps and conductive traces to finish the fabrication of a wiring board in accordance with the first embodiment of the present invention;

FIG. 12 is a cross-sectional view of a semiconductor assembly with a chip electrically connected to the wiring board of FIG. 9 in accordance with the first embodiment of the present invention;

FIG. 13 is a cross-sectional view of a stacking structure on a carrier film in accordance with the second embodiment of the present invention;

FIG. 14 is a cross-sectional view showing the metal slug of FIG. 1 is attached to the carrier film of FIG. 13 in accordance with the second embodiment of the present invention;

FIG. 15 is a cross-sectional view showing the stacking structure of FIG. 14 is subjected to a lamination process in accordance with the second embodiment of the present invention;

FIG. 16 is a cross-sectional view showing excess adhesive and the carrier film are removed from the structure of FIG. 15 in accordance with the second embodiment of the present invention;

FIG. 17 is a cross-sectional view showing the structure of FIG. 16 is provided with moisture inhibiting caps and conductive traces to finish the fabrication of a wiring board in accordance with the second embodiment of the present invention;

FIG. 18 is a cross-sectional view of a metal plate on a carrier film in accordance with the third embodiment of the present invention;

FIG. 19 is a cross-sectional view showing the metal slug of FIG. 1 is attached to the carrier film of FIG. 18 in accordance with the third embodiment of the present invention;

FIG. 20 is a cross-sectional view showing the structure of FIG. 19 is provided with a plastic embedding compound in accordance with the third embodiment of the present invention;

FIG. 21 is a cross-sectional view showing the upper portion of the plastic embedding compound is removed from the structure of FIG. 20 in accordance with the third embodiment of the present invention;

FIG. 22 is a cross-sectional view showing the carrier film is removed from the structure of FIG. 21 in accordance with the third embodiment of the present invention;

FIG. 23 is a cross-sectional view showing the structure of FIG. 22 is provided with moisture inhibiting caps and conductive traces to finish the fabrication of a wiring board in accordance with the third embodiment of the present invention;

FIG. 24 is a cross-sectional view of a stacking structure on a carrier film in accordance with the fourth embodiment of the present invention;

FIG. 25 is a cross-sectional view showing the metal slug of FIG. 1 and metal posts are attached to the carrier film of FIG. 24 in accordance with the fourth embodiment of the present invention;

FIG. 26 is a cross-sectional view showing the stacking structure of FIG. 25 is subjected to a lamination process in accordance with the fourth embodiment of the present invention;

FIG. 27 is a cross-sectional view showing excess adhesive and the carrier film are removed from the structure of FIG. 26 in accordance with the fourth embodiment of the present invention;

FIGS. 28, 29 and 30 are cross-sectional and bottom and top perspective views showing the structure of FIG. 27 is provided with moisture inhibiting caps and conductive traces to finish the fabrication of a wiring board in accordance with the fourth embodiment of the present invention;

FIG. 31 is a cross-sectional view of the metal slug of FIG. 1 and metal posts on a carrier film in accordance with the fifth embodiment of the present invention;

FIG. 32 is a cross-sectional view showing the structure of FIG. 31 is provided with a plastic embedding compound in accordance with the fifth embodiment of the present invention;

FIG. 33 is a cross-sectional view showing the upper portion of the plastic embedding compound and the carrier film are removed from the structure of FIG. 32 in accordance with the fifth embodiment of the present invention; and

FIG. 34 is a cross-sectional view showing the structure of FIG. 33 is provided with moisture inhibiting caps and conductive traces to finish the fabrication of a wiring board in accordance with the fifth embodiment of the present invention.

### DETAILED DESCRIPTION OF THE PREFERRED EMBODIMENTS

Hereafter, examples will be provided to illustrate the embodiments of the present invention. Advantages and effects of the invention will become more apparent from the disclosure of the present invention. It should be noted that these accompanying figures are simplified and illustrative. The quantity, shape and size of components shown in the figures may be modified according to practical conditions, and the arrangement of components may be more complex. Other various aspects also may be practiced or applied in the invention, and various modifications and variations can be made without departing from the spirit of the invention based on various concepts and applications.

### Embodiment 1

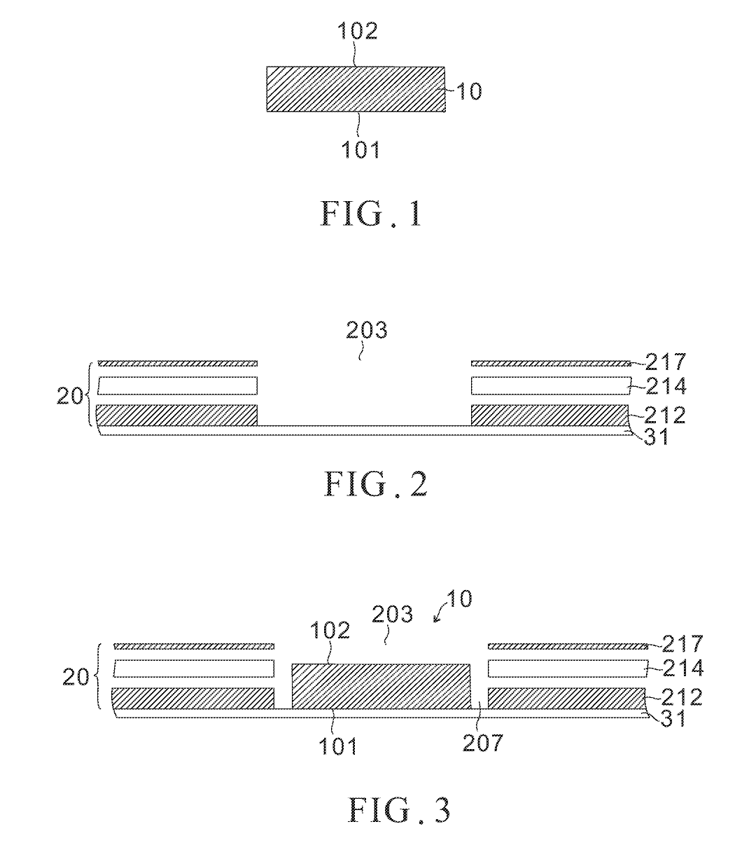

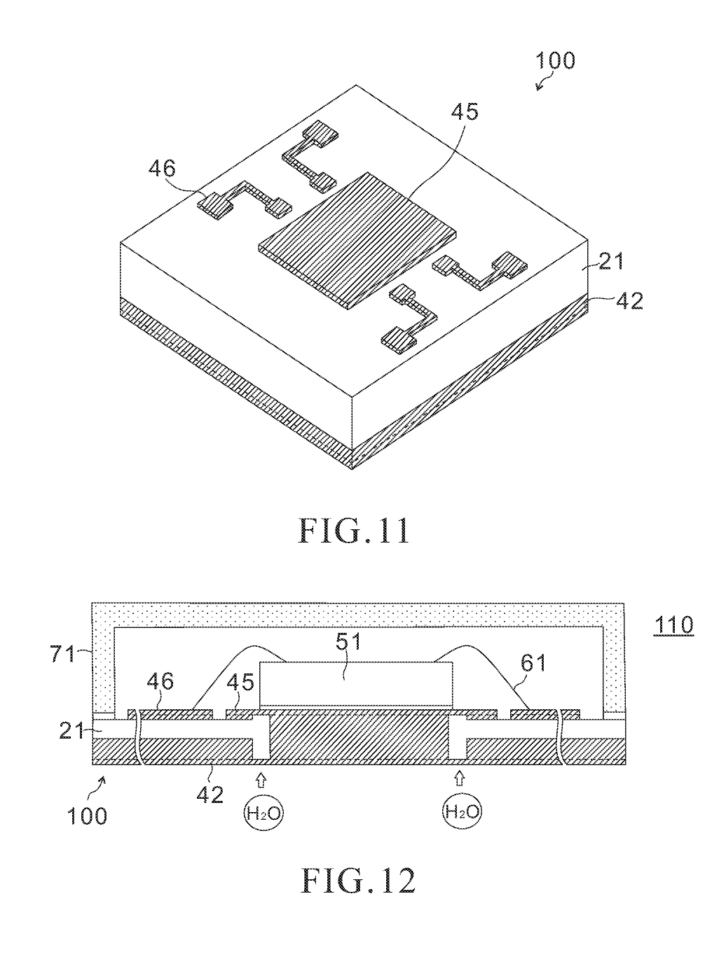

FIGS. 1-11 are schematic views showing a method of making a thermally enhanced wiring board that includes a metal slug, a resin core, moisture inhibiting caps and conductive traces in accordance with an embodiment of the present invention.

FIG. 1 is a cross-sectional view of a metal slug 10 having opposite planar first and second sides 101, 102. The metal slug 10 can be made of copper, aluminum, nickel or other metallic material. In this embodiment, the metal slug 10 is a copper slug with a thickness of 0.4 mm.

FIG. 2 is a cross-sectional view of a stacking structure 20 having an aperture 203 on a carrier film 31. The stacking structure 20 includes a first metal layer 212, a binding film 214 and a second metal layer 217. The aperture 203 is formed by punching through the first metal layer 212, the binding film 214 and the second metal layer 217, and has a dimension that is almost the same or a little larger than the metal slug 10. Also, the aperture 203 may be formed by other techniques such as laser cutting with or without wet etching The carrier film 31 typically is a tape, and the first metal layer 212 is attached to the carrier film 31 by the adhesive property of the carrier film 31. In this stacking structure 20, the binding film 214 is disposed between the first metal layer 212 and the second metal layer 217. The first metal layer 212 and the second metal layer 217 are typically made of copper and each have two opposite planar surfaces facing towards the upward and downward directions, respectively. The binding film 214 can be various dielectric films or prepregs formed from numerous organic or inorganic electrical insulators. For instance, the binding film 214 can initially be a prepreg in which thermosetting epoxy in resin form impregnates a reinforcement and is partially cured to an intermediate stage. The epoxy can be FR-4 although other epoxies such as polyfunctional and bismaleimide triazine (BT) are suitable. For specific applications, cyanate esters, polyimide and PTFE are also suitable. The reinforcement can be E-glass although other reinforcements such as S-glass, D-glass, quartz, kevlar aramid and paper are suitable. The reinforcement can also be woven, non-woven or random microfiber. A filler such as silica (powdered fused quartz) can be added to the prepreg to improve thermal conductivity, thermal shock resistance and thermal expansion matching Commercially available prepregs such as SPEEDBOARD C prepreg by W.L. Gore & Associates of Eau Claire, Wis. are suitable. In this embodiment, the binding film 214 is a prepreg with B-stage uncured epoxy provided as a non-solidified sheet, and the first metal layer 212 and the second metal layer 217 are copper layers of 0.2 mm and 0.025 mm in thickness, respectively.

FIG. 3 is a cross-sectional view of the structure with the metal slug 10 attached on the carrier film 31. The metal slug 10 is aligned with the aperture 203 of the stacking structure 20 with the first side 101 facing towards the carrier film 31, and is inserted into the aperture 203 without contacting the stacking structure 20. As a result, a gap 207 is located in the aperture 203 between the metal slug 10 and the stacking structure 20. The gap 207 laterally surrounds the metal slug 10 and is laterally surrounded by the stacking structure 20. In this illustration, the metal slug 10 is attached to the carrier film 31 by the adhesive property of the carrier film 31. Also, the metal slug 10 may be attached to the carrier film 31 by dispensing extra adhesive.

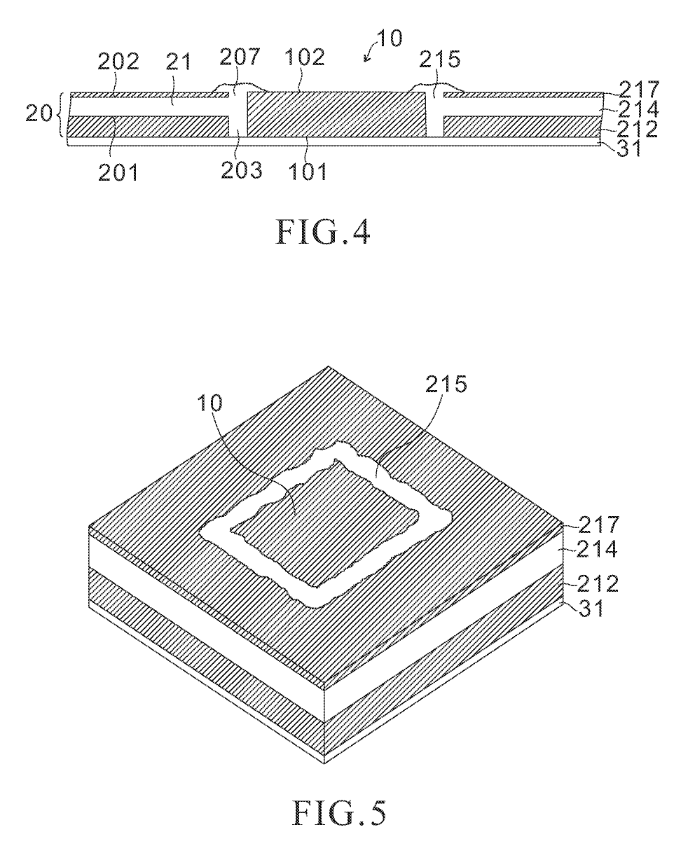

FIGS. 4 and 5 are cross-sectional and top perspective views, respectively, of the structure in which the gap 207 is filled with an adhesive 215 squeezed out from the binding film 214. By applying heat and pressure, the binding film 214 is squeezed and part of the adhesive in the binding film 214 flows into the gap 207. The bonding film 214 is compressed by applying downward pressure to the second metal layer 217 and/or upward pressure to the carrier film 31, thereby moving the first metal layer 212 and the second metal layer 217 towards one another and applying pressure to the binding film 214 while simultaneously applying heat to the binding film 214. The binding film 214 becomes compliant enough under the heat and pressure to conform to virtually any shape. As a result, the binding film 214 sandwiched between the first metal layer 212 and the second metal layer 217 is compressed, forced out of its original shape and flows into the gap 207. The first metal layer 212 and the second metal layer 217 continue to move towards one another, and the binding film 214 remains sandwiched between and continues to fill the reduced space between the first metal layer 212 and the second metal layer 217. Meanwhile, the adhesive 215 squeezed out from the binding film 214 fills the gap 207. In this illustration, the adhesive 215 squeezed out from the binding film 214 also rises slightly above the aperture 203 and overflows onto the top surfaces of the metal slug 10 and the second metal layer 217. This may occur due to the binding film 214 being slightly thicker than necessary. As a result, the adhesive 215 squeezed out from the binding film 214 creates a thin coating on the top surfaces of the metal slug 10 and the second metal layer 217. The motion eventually stops when the second metal layer 217 becomes coplanar with the metal slug 10 at the top surface, but heat continues to be applied to the binding film 214 and the squeezed out adhesive 215, thereby converting the B-stage molten uncured epoxy into C-stage cured or hardened epoxy.

At this stage, the stacking structure 20 is bonded with sidewalls of the metal slug 10 by the adhesive 215 squeezed out from the binding film 214. The binding film 214 as solidified provides a secure robust mechanical bond between the first metal layer 212 and the second metal layer 217. Accordingly, the metal slug 10 is incorporated with a resin core 21 with the adhesive 215 sandwiched therebetween. The resin core 21 has a first side 201 bonded to the first metal layer 212 and an opposite second side 202 bonded to the second metal layer 217.

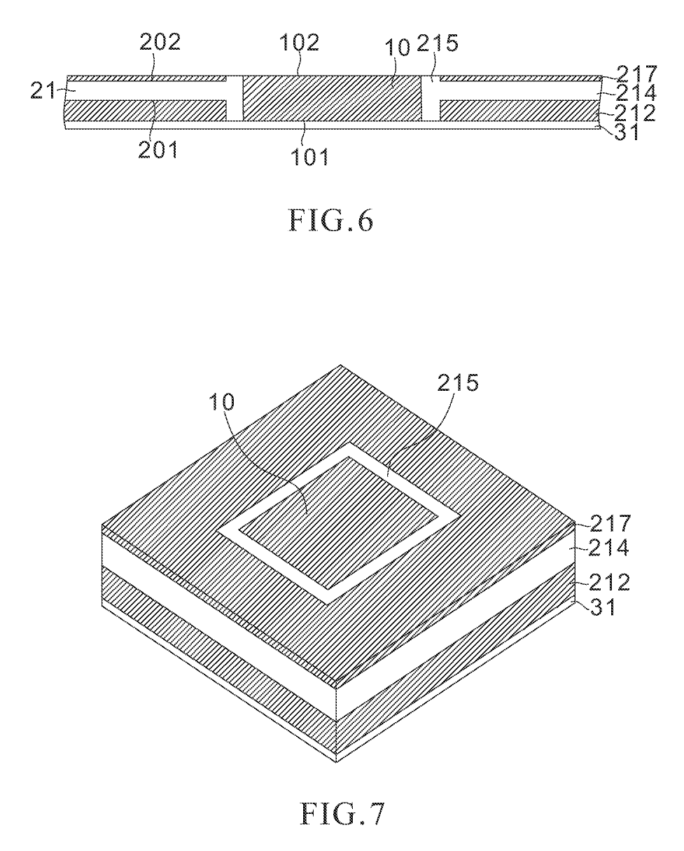

FIGS. 6 and 7 are cross-sectional and top perspective views, respectively, of the structure after removal of excess adhesive that overflows onto the metal slug 10 and second metal layer 217. The excess adhesive can be removed by lapping/grinding. After lapping/grinding, the metal slug 10, the second metal layer 217 and the adhesive 215 squeezed out from the binding film 214 are essentially coplanar with one another at a smoothed lapped/ground top surface.

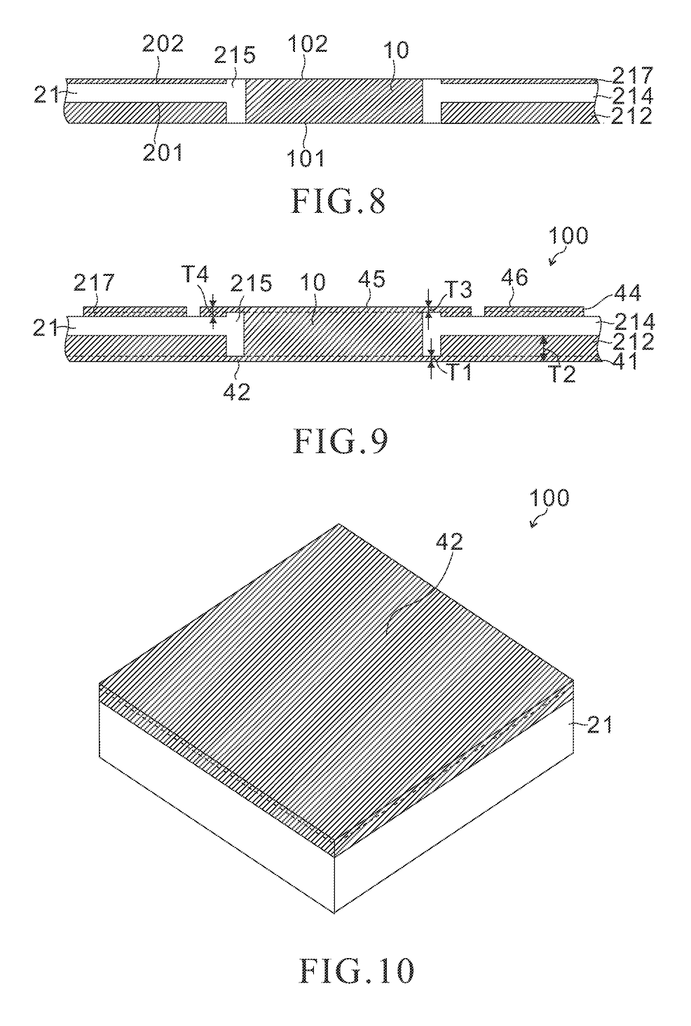

FIG. 8 is a cross-sectional view of the structure after removal of the carrier film 31. The carrier film 31 is detached from the metal slug 10, the first metal layer 212 and the squeezed out adhesive 215 to expose the metal slug 10 and the first metal layer 212. Accordingly, the adhesive 215 has two opposite exposed surfaces essentially coplanar with the first and second sides 101, 102 of the metal slug 10 and the outer planar surfaces of the first and second metal layers 212, 217 in the downward and upward directions, respectively.

FIGS. 9, 10 and 11 are cross-sectional, bottom and top perspective views, respectively, of the structure provided with first and second moisture inhibiting caps 42, 45 and conductive traces 46. The bottom surface of the structure can be metallized to form a bottom plated layer 41 (typically a copper layer) as a single layer or multiple layers by numerous techniques, such as electroplating, electroless plating, evaporating, sputtering or their combinations. For instance, the structure can be first dipped in an activator solution to render the bottom surface of the structure catalytic to electroless copper, then a thin copper layer is electrolessly plated to serve as the seeding layer before a second copper layer is electroplated on the seeding layer to a desirable thickness. Alternatively, the seeding layer can be formed by sputtering a thin film such as titanium/copper onto the bottom surface of the structure before depositing the electroplated copper layer on the seeding layer. Accordingly, the first moisture inhibiting cap 42, consisting of the first metal layer 212 and the bottom plated layer 41, includes a selected portion that laterally extends from the first side 101 of the metal slug 10 to the first metal layer 212 on the resin core 21. In this illustration, the first moisture inhibiting cap 42 is an unpatterned metal layer, and has a first thickness T1 (about 0.5 to 50 microns) where it contacts the squeezed out adhesive 215, a second thickness T2 where it contacts the resin core 21 that further includes the thickness of the first metal layer 212 and thus is larger than the first thickness T1, and a flat surface that faces in the downward direction. The metal slug 10, the first metal layer 212 and the bottom plated layer 41 are shown as a single layer for convenience of illustration. The boundary (shown in dashed line) between the metal layers may be difficult or impossible to detect since copper is plated on copper. However, the boundary between the bottom plated layer 41 and the squeezed out adhesive 215 is clear.

Also, the top surface of the structure can be metallized to form a top plated layer 44 by the same activator solution, electroless copper seeding layer and electroplated copper layer. Once the desired thickness is achieved, a metal patterning process is executed to form the second moisture inhibiting cap 45 and the conductive traces 46. The second moisture inhibiting cap 45, consisting of the top plated layer 44 and the second metal layer 217, includes a selected portion that extends from the second side 102 of the metal slug 10 to the second metal layer 217 on the resin core 21, and has a third thickness T3 (about 0.5 to 50 microns) where it contacts the squeezed out adhesive 215, a fourth thickness T4 where it contacts the resin core 21 that further includes the thickness of the second metal layer 217 and thus is larger than the third thickness T3, and a flat surface that faces in the upward direction. The conductive traces 46, consisting of the top plated layer 44 and the second metal layer 217, contact and laterally extend on the second side 202 of the resin core 21, and have a combined thickness of the second metal layer 217 and the top plated layer 44. The metal patterning techniques include wet etching, electro-chemical etching, laser-assisted etching, and their combinations with an etch mask (not shown) thereon that defines the second moisture inhibiting cap 45 and the conductive traces 46.

Accordingly, as shown in FIGS. 9, 10 and 11, a thermally enhanced wiring board 100 is accomplished and includes a metal slug 10, a resin core 21, a squeezed out adhesive 215, first and second moisture inhibiting caps 42, 45 and conductive traces 46. The resin core 21 covers and surrounds sidewalls of the metal slug 10 and is mechanically connected to sidewalls of the metal slug 10 by the squeezed out adhesive 215 between the metal slug 10 and the resin core 21. The first and second moisture inhibiting caps 42, 45 completely covers the adhesive 215 between the metal slug 10 and the resin core 21 and interfaces between the metal slug 10 and the adhesive 215 further laterally extend on both opposite sides of the resin core 21 from below and above, respectively. The conductive traces 46 are spaced from the second moisture inhibiting cap 45 and can provide electrical contacts for chip connection and external connection from the upward direction.

FIG. 12 is a cross-sectional view of a semiconductor assembly 110 with a semiconductor device 51 electrically connected to the thermally enhanced wiring board 100 illustrated in FIG. 9. The semiconductor device 51, illustrated as a chip, is mounted on the second moisture inhibiting cap 45, and electrically connected to the conductive traces 46 of the thermally enhanced wiring board 100 via bonding wires 61. Further, a lid 71 is mounted on the thermally enhanced wiring board 100 to enclose the semiconductor device 51 therein from above. Accordingly, even if cracks are caused by mismatched CTE between the metal slug 10 and the adhesive 215, the first moisture inhibiting cap 42 of the wiring board 100 can restrict the passage of moisture through the cracks from ambiance into the interior of the semiconductor assembly 110. Further, the heat generated by the semiconductor device 51 can be transferred to the metal slug 10 and further spread out to the first moisture inhibiting cap 42 that has a larger thermal dissipation surface area than the metal slug 10.

### Embodiment 2

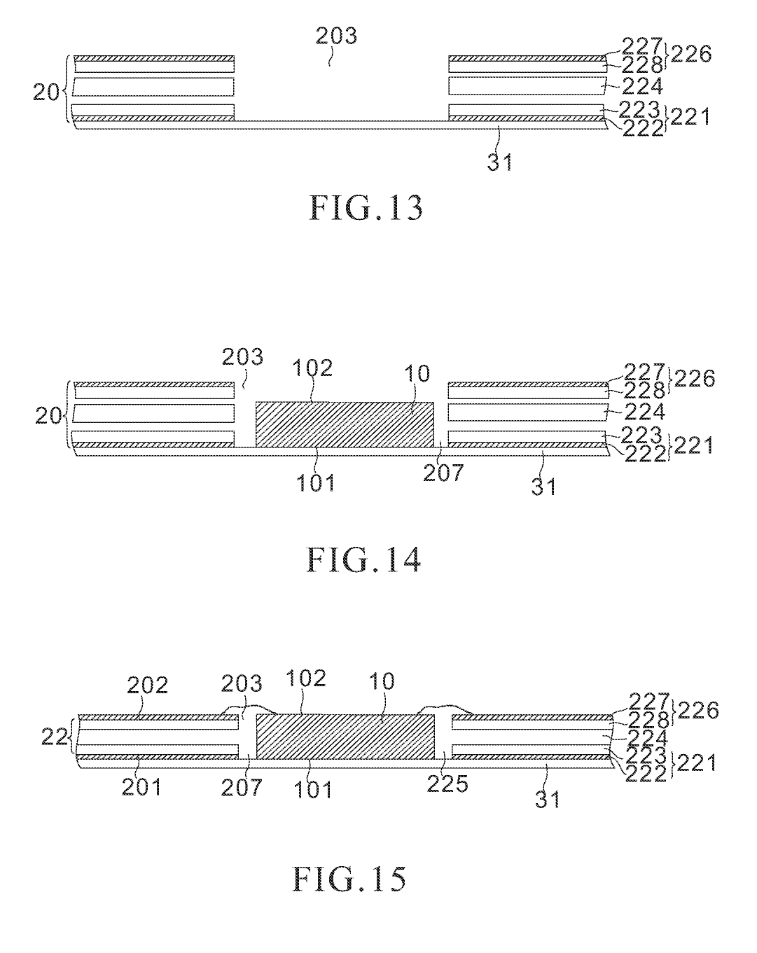

FIGS. 13-17 are schematic views showing another method of making a thermally enhanced wiring board in which another stacking structure is provided to form a resin core in accordance with another embodiment of the present invention.

For purposes of brevity, any description in Embodiment 1 above is incorporated herein insofar as the same is applicable, and the same description need not be repeated.

FIG. 13 is a cross-sectional view of the structure with a stacking structure 20 on a carrier film 31. The stacking structure 20 includes a first laminate substrate 221, a binding film 224 and a second laminate substrate 226. The stacking structure 20 has an aperture 203 that extends through the first laminate substrate 221, the binding film 224 and the second laminate substrate 226. In this illustration, the first laminate substrate 221 includes a first metal layer 222 disposed on a first dielectric layer 223, and the second laminate substrate 226 includes a second metal layer 227 disposed on a second dielectric layer 228. The first and second dielectric layers 223, 228 typically are made of epoxy resin, glass-epoxy, polyimide or the like, and have a thickness of 50 microns. The first and second metal layers 222, 227 typically are made of copper and have a thickness of 35 microns. In this stacking structure 20, the binding film 224 is disposed between the first laminate substrate 221 and the second laminate substrate 226, and the first metal layer 222 of the first laminate substrate 221 and the second metal layer 227 of the second laminate substrate 226 respectively face in the downward and upward directions. By the adhesive property of the carrier film 31, the stacking structure 20 is attached to the carrier film 31 with the first metal layer 222 of the first laminate substrate 221 in contact with the carrier film 31.

FIG. 14 is a cross-sectional view of the structure with the metal slug 10 of FIG. 1 attached to the carrier film 31. The metal slug 10 is inserted into the aperture 203 of the stacking structure 20 with the first side 101 facing towards the carrier film 31 and is attached to the carrier film 31 without contacting the stacking structure 20. As a result, a gap 207 is located in the aperture 203 between the metal slug 10 and the stacking structure 20.

FIG. 15 is a cross-sectional view of the structure in which the gap 207 is filled with an adhesive 225 squeezed out from the binding film 224. By applying heat and pressure, the binding film 224 is squeezed and part of the adhesive in the binding film 224 flows into the gap 207. After the squeezed out adhesive 225 fills up the gap 207, the binding film 224 and the squeezed out adhesive 225 are solidified. Accordingly, the metal slug 10 is bonded to a resin core 22 by the squeezed out adhesive 225 in the gap 207. In this embodiment, the resin core 22 includes the first dielectric layer 223, the cured binding film 224 and the second dielectric layer 228, and has a first side 201 bonded to the first metal layer 222 and an opposite second side 202 bonded to the second metal layer 227. The cured binding film 224 is integrated with the first dielectric layer 223 of the first laminate substrate 221 and the second dielectric layer 228 of the second laminate substrate 226, and provides secure robust mechanical bonds between the first laminate substrate 221 and the second laminate substrate 226. The squeezed out adhesive 225 in the gap 207 provides secure robust mechanical bonds between the metal slug 10 and the resin core 22. In this illustration, the adhesive 225 squeezed out from the binding film 224 also rises slightly above the aperture 203 and overflows onto the top surfaces of the metal slug 10 and the second metal layer 227.

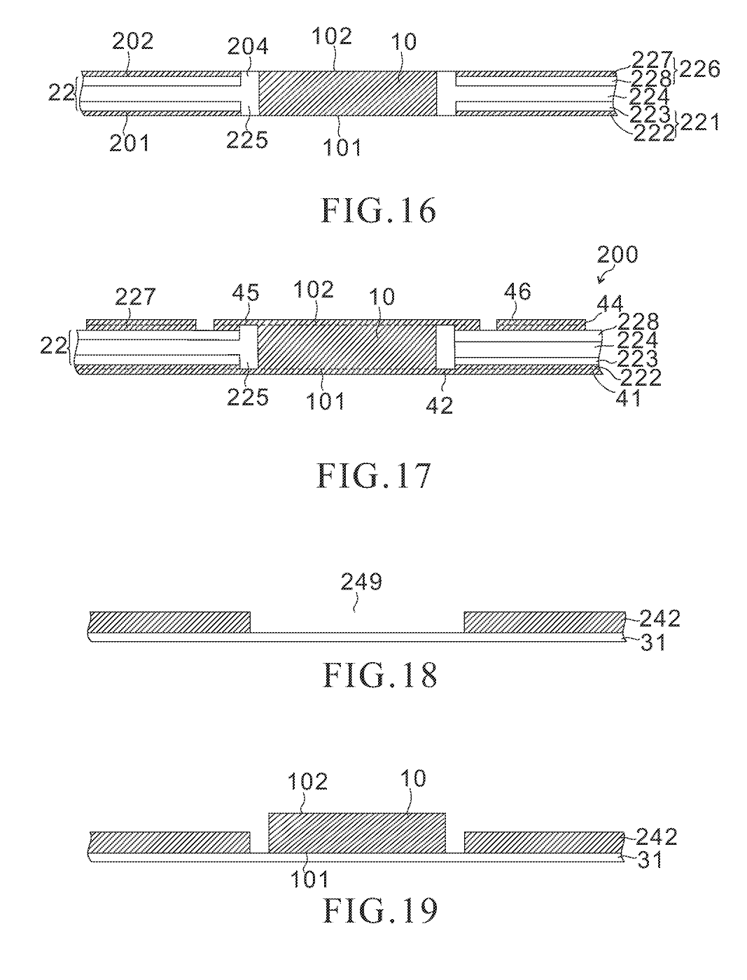

FIG. 16 is a cross-sectional view of the structure after removal of excess adhesive and the carrier film 31. The excess adhesive on the metal slug 10 and second metal layer 227 is removed by lapping/grinding to create a smoothed lapped/ground top surface. The carrier film 31 is detached from the metal slug 10, the first metal layer 222 and the squeezed out adhesive 225 to expose the metal slug 10 and the first metal layer 222. Accordingly, the adhesive 225 has two opposite exposed surfaces essentially coplanar with the first and second sides 101, 102 of the metal slug 10 and the outer surfaces of the first and second metal layers 222, 227 in the downward and upward directions, respectively.

FIG. 17 is a cross-sectional view of the structure provided with first and second moisture inhibiting caps 42, 45 and conductive traces 46. The first moisture inhibiting cap 42 is formed by depositing a bottom plated layer 41, which is combined with the first metal layer 222 from below. Accordingly, the first moisture inhibiting cap 42 includes the first metal layer 222 and the bottom plated layer 41, and contacts and covers the metal slug 10, the resin core 22 and the squeezed out adhesive 225 from below. Also, the top surface of the structure is metallized to form a top plated layer 44, followed by a metal patterning process to form the second moisture inhibiting cap 45 and the conductive traces 46. The second moisture inhibiting cap 45 contacts and covers the metal slug 10, the resin core 22 and the squeezed out adhesive 225 from above. The conductive traces 46 contact and laterally extend on the second side 202 of the resin core 22.

Accordingly, as shown in FIG. 17, a thermally enhanced wiring board 200 is accomplished and includes a metal slug 10, a resin core 22, a squeezed out adhesive 225, first and second moisture inhibiting caps 42, 45 and conductive traces 46. The resin core 22 is mechanically connected to the metal slug 10 by the squeezed out adhesive 225. The first and second moisture inhibiting caps 42, 45 completely cover the adhesive 225 and interfaces between the metal slug 10 and the adhesive 225 and further laterally extend on the resin core 22 from above and below, respectively. The conductive traces 46 are spaced from the second moisture inhibiting cap 45 and provide electrical contacts for chip connection and external connection from above.

### Embodiment 3

FIGS. 18-23 are schematic views showing yet another method of making a thermally enhanced wiring board with a plastic embedding compound laterally covering sidewalls of a metal slug in accordance with yet another embodiment of the present invention.

For purposes of brevity, any description in the aforementioned Embodiments is incorporated herein insofar as the same is applicable, and the same description need not be repeated.

FIG. 18 is a cross-sectional view of the structure with a metal plate 242 on a carrier film 31. The metal plate 242 includes an opening 249 and is attached to the carrier film 31 by the adhesive property of the carrier film 31. The metal plate 242 can be made of copper, aluminum, nickel or other metallic material. In this embodiment, the metal plate 242 is a copper plate with a thickness of 0.2 mm. The opening 249 can be formed by punching, stamping, etching or mechanical routing, and typically has a dimension that is almost the same or a little larger than a subsequently disposed metal slug 10.

FIG. 19 is a cross-sectional view of the structure with the metal slug 10 of FIG. 1 attached to a carrier film 31. The metal slug 10 is partially inserted into the opening 249 of the metal plate 242 and is attached to the carrier film 31 with the first side 101 in contact with the carrier film 31.

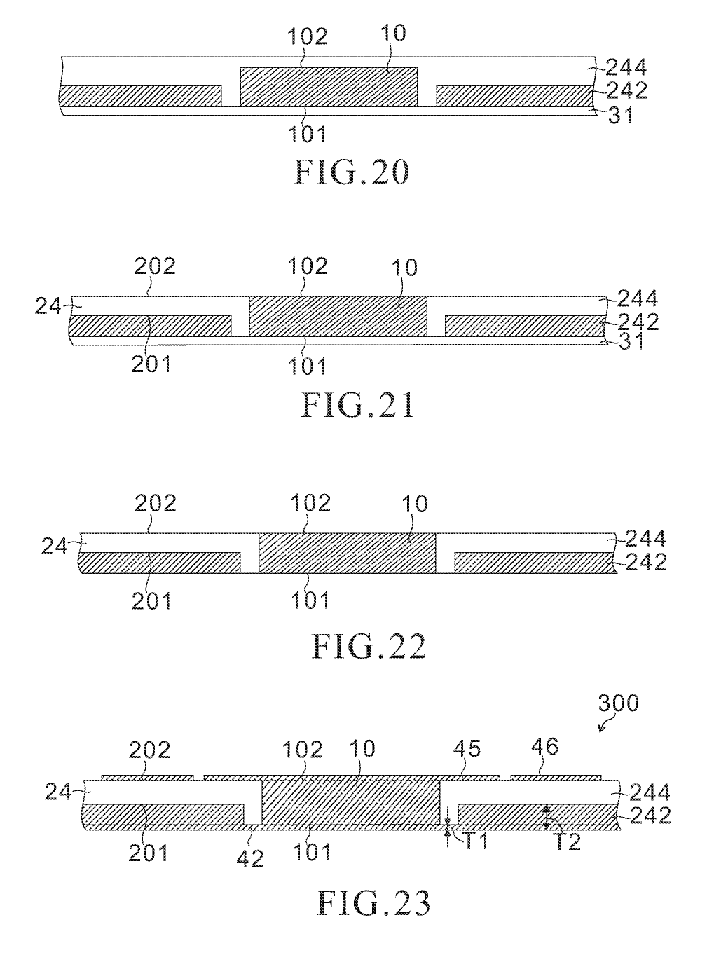

FIG. 20 is a cross-sectional view of the structure provided with a plastic embedding compound 244. The plastic embedding compound 244 can be deposited by a molding process or other methods such as lamination of epoxy or polyimide. The plastic embedding compound 244 covers the metal slug 10 and the metal plate 242 from above, laterally covers and surrounds and conformally coats the sidewalls of the metal slug 10, and extends laterally from the metal slug 10 to peripheral edges of the structure. Further, the plastic embedding compound 244 extends into a gap between the metal slug 10 and the metal plate 242 and contacts the carrier film 31.

FIG. 21 is a cross-sectional view of the structure with the second side 102 of the metal slug 10 exposed from above. The upper portion of the plastic embedding compound 244 can be removed by grinding. After the grinding, the metal slug 10 and the plastic embedding compound 244 are essentially coplanar with each other at a smoothed lapped top surface. Accordingly, the metal slug 10 is incorporated with a resin core 24 that has a first side 201 bonded to the metal plate 242 and an opposite second side 202 essentially coplanar with the second side 102 of the metal slug 10 in the upward direction.

FIG. 22 is a cross-sectional view of the structure after removal of the carrier film 31. The carrier film 31 is detached from the metal slug 10 and the metal plate 242 to expose the first side 101 of the metal slug 10 and the metal plate 242.

FIG. 23 is a cross-sectional view of the structure provided with first and second moisture inhibiting caps 42, 45 and conductive traces 46. The first and second moisture inhibiting caps 42, 45 and conductive traces 46 can be deposited by a sputtering process and then an electrolytic plating process to achieve desired thickness. Once the desired thickness is achieved, a metal patterning process is executed to form the second moisture inhibiting cap 45 and the conductive traces 46. The first moisture inhibiting cap 42 is an unpatterned metal layer that includes the metal plate 242 and completely covers interfaces between the metal slug 10 and the plastic embedding compound 244 from below. In this illustration, the first moisture inhibiting cap 42 has a first thickness T1 (about 0.5 to 50 microns) where it is adjacent to the interfaces between the metal slug 10 and the plastic embedding compound 244 and a second thickness T2 that includes the thickness of the metal plate 242 and thus is larger than the first thickness T1. The second moisture inhibiting cap 45 is spaced from the conductive traces 46 and completely covers interfaces between the metal slug 10 and the plastic embedding compound 244 from above and has a thickness of 0.5 to 50 microns. The conductive traces 46 laterally extend on the second side 202 of the resin core 24 and have a thickness of 0.5 to 50 microns.

Accordingly, as shown in FIG. 23, a thermally enhanced wiring board 300 is accomplished and includes a metal slug 10, a resin core 24, first and second moisture inhibiting caps 42, 45 and conductive traces 46. The resin core 24 covers and surrounds sidewalls of the metal slug 10 and is bonded to the metal slug 10. The first moisture inhibiting cap 42 laterally extends from the first side 101 of the metal slug 10 to peripheral edges of the wiring board 300 and has a non-uniform thickness. As an alternative, the structure may be formed to be devoid of the metal plate 242, and thus the first moisture inhibiting cap 42 can have a uniform thickness. The second moisture inhibiting cap 45 laterally extends on the second side 102 of the metal slug 10 and the second side 202 of the resin core 24 and is spaced from peripheral edges of the wiring board 300. The conductive traces 46 are spaced from the second moisture inhibiting cap 45 and provide electrical contacts for chip connection and external connection from above.

### Embodiment 4

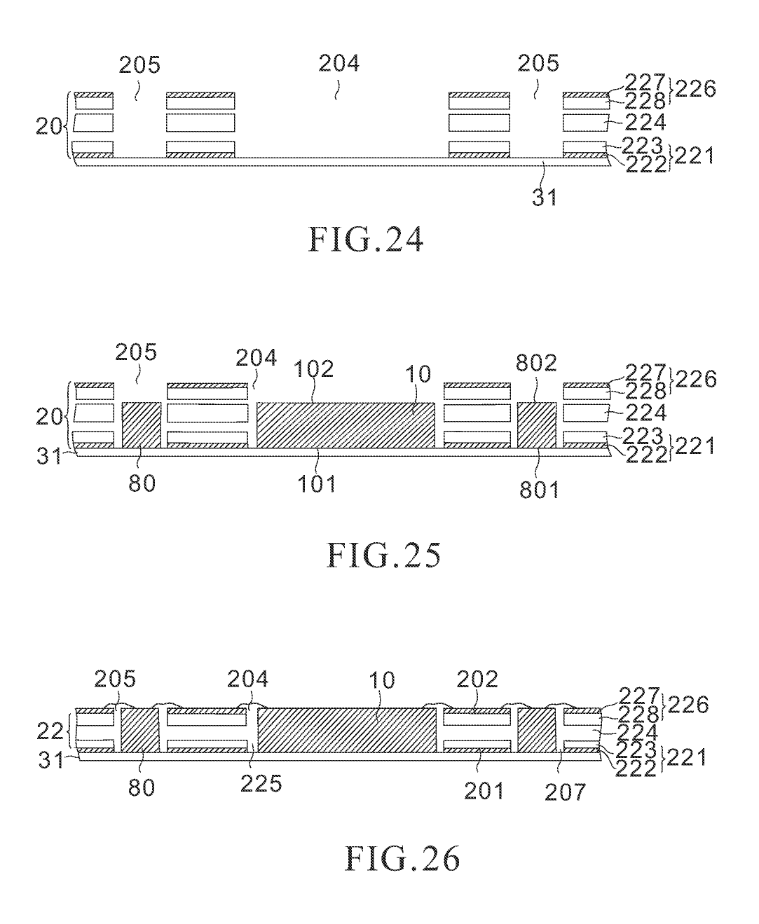

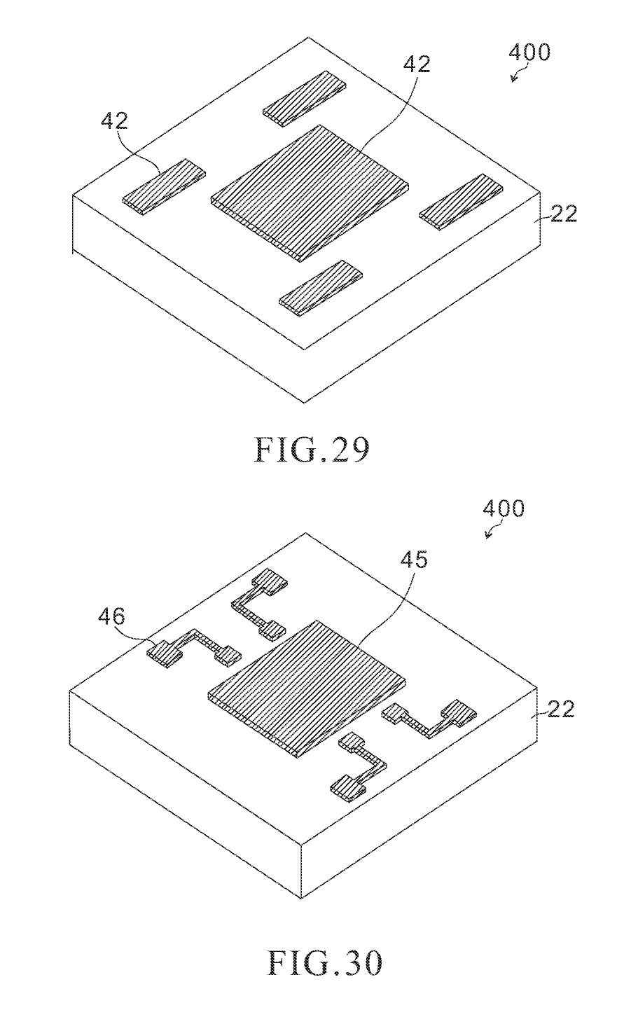

FIGS. 24-30 are schematic views showing a method of making a thermally enhanced wiring board with metal posts as vertical electrical connections in accordance with another embodiment of the present invention.

For purposes of brevity, any description in aforementioned Embodiments above is incorporated herein insofar as the same is applicable, and the same description need not be repeated.

FIG. 24 is a cross-sectional view of the structure with a stacking structure 20 on a carrier film 31. The stacking structure 20 is similar to that illustrated in FIG. 13, except that the stacking structure 20 has first and second apertures 204, 205 that extend through the first laminate substrate 221, the binding film 224 and the second laminate substrate 226 in this embodiment.

FIG. 25 is a cross-sectional view of the structure with the metal slug 10 of FIG. 1 and metal posts 80 attached to the carrier film 31. The metal slug 10 is inserted into the first aperture 204 of the stacking structure 20, whereas the metal posts 80 are inserted into second apertures 205 of the stacking structure 20. The metal posts 80 each have opposite planar first and second sides 801, 802 substantially coplanar with the first and second sides 101, 102 of the metal slug 10, respectively. The metal slug 10 and the metal posts 80 are attached on the carrier film 31 with their first sides 101, 801 facing towards the carrier film 31. The metal posts 80 can be made of any electrically conductive material. In this embodiment, the metal posts 80 are copper posts each with a thickness of 0.4 mm

FIG. 26 is a cross-sectional view of the structure with an adhesive 225 squeezed out from the binding film 224 into gaps 207 between the metal slug 10 and the stacking structure 20 and between the metal posts 80 and the stacking structure 20. By applying heat and pressure, the binding film 224 is squeezed and part of the adhesive in the binding film 224 flows into the gaps 207. After the squeezed out adhesive 225 fills up the gaps 207, the binding film 224 and the squeezed out adhesive 225 are solidified. Accordingly, the metal slug 10 and the metal posts 80 are bonded to a resin core 22 by the squeezed out adhesive 225 in the gaps 207. In this illustration, the resin core 22 includes the first dielectric layer 223, the cured binding film 224 and the second dielectric layer 228, and has a first side 201 bonded to the first metal layer 222 and an opposite second side 202 bonded to the second metal layer 227. The squeezed out adhesive 225 in the gaps 207 provides secure robust mechanical bonds between the metal slug 10 and the resin core 22 and between the metal posts and the resin core 22. The adhesive 225 squeezed out from the binding film 224 also rises slightly above the first and second apertures 204, 205 and overflows onto the top surfaces of the metal slug 10, the second metal layer 227 and the metal posts 80.

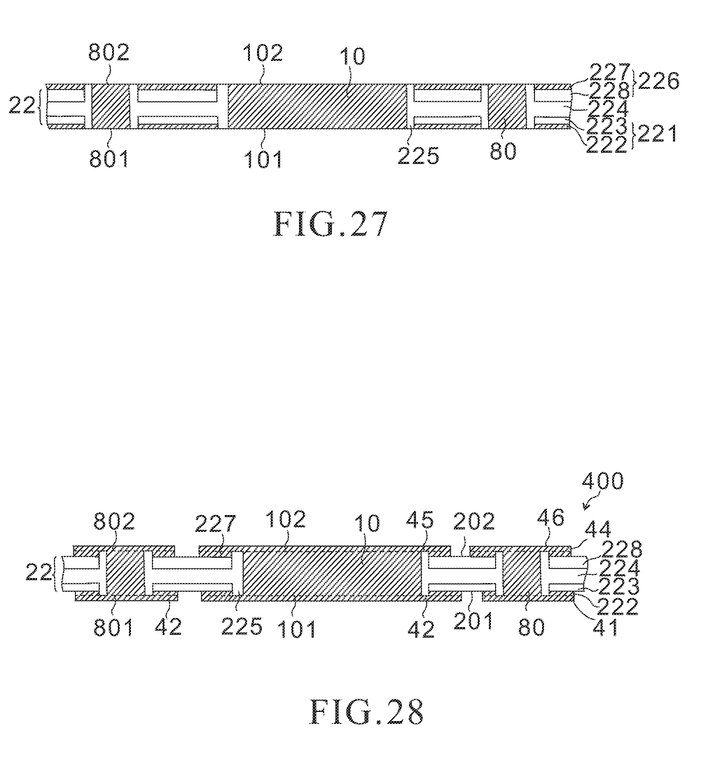

FIG. 27 is a cross-sectional view of the structure after removal of excess adhesive and the carrier film 31. The excess adhesive on the metal slug 10, the second metal layer 227 and the metal posts 80 is removed by lapping/grinding to create a smoothed lapped/ground top surface. The carrier film 31 is detached from the metal slug 10, the first metal layer 222, the metal posts 80 and the squeezed out adhesive 225. As a result, the adhesive 225 has two opposite exposed surfaces essentially coplanar with the first and second sides 101, 102 of the metal slug 10, the first and second sides 801, 802 of the metal posts 80 and the outer surfaces of the first and second metal layers 222, 227 in the downward and upward directions, respectively.

FIGS. 28, 29 and 30 are cross-sectional, bottom and top perspective views, respectively, of the structure provided with first and second moisture inhibiting caps 42, 45 and conductive traces 46. The bottom surface of the structure is metallized to form a bottom plated layer 41, followed by a metal patterning process to form plural first moisture inhibiting caps 42 spaced from each other. One of the first moisture inhibiting caps 42 includes a selected portion that laterally extends from the first side 101 of the metal slug 10 to the first metal layer 222 on the resin core 22, and the others of the first moisture inhibiting caps 42 each include a selected portion that laterally extends from the first side 801 of the metal post 80 to the first metal layer 222 on the resin core 22. Also, the top surface of the structure is metallized to form a top plated layer 44, followed by a metal patterning process to form the second moisture inhibiting cap 45 and the conductive traces 46. The second moisture inhibiting cap 45 includes a selected portion that laterally extends from the second side 102 of the metal slug 10 to the second metal layer 227 on the resin core 22. The conductive traces 46 contact and laterally extend on the second side 202 of the resin core 22, and have selected portions that laterally extend from the second side 802 of the metal posts 80 to the second metal layer 227 on the resin core 22.

Accordingly, as shown in FIGS. 28, 29 and 30, a thermally enhanced wiring board 400 is accomplished and includes a metal slug 10, metal posts 80, a resin core 22, a squeezed out adhesive 225, first and second moisture inhibiting caps 42, 45 and conductive traces 46. The resin core 22 covers and surrounds sidewalls of the metal slug 10 and the metal posts 80, and is mechanically connected to the metal slug 10 and the metal posts 80 by the squeezed out adhesive 225 between the metal slug 10 and the resin core 22 and between the metal posts 80 and the resin core 22. The first moisture inhibiting caps 42 completely cover the adhesive 225 and interfaces between the metal slug 10 and the adhesive 225 and between the metal posts 80 and the adhesive 225 and further laterally extend on the resin core 22 from below. The second moisture inhibiting cap 45 completely covers the adhesive 225 between the metal slug 10 and the resin core 22 and interfaces between the metal slug 10 and the adhesive 225 and further laterally extends on the resin core 22 from above. The conductive traces 46 laterally extend on the resin core 22 and further completely cover the adhesive 225 between the metal posts 80 and the resin core 22 and interfaces between the metal posts 80 and the adhesive 225 and are electrically connected to the metal posts 80 from above.

### Embodiment 5

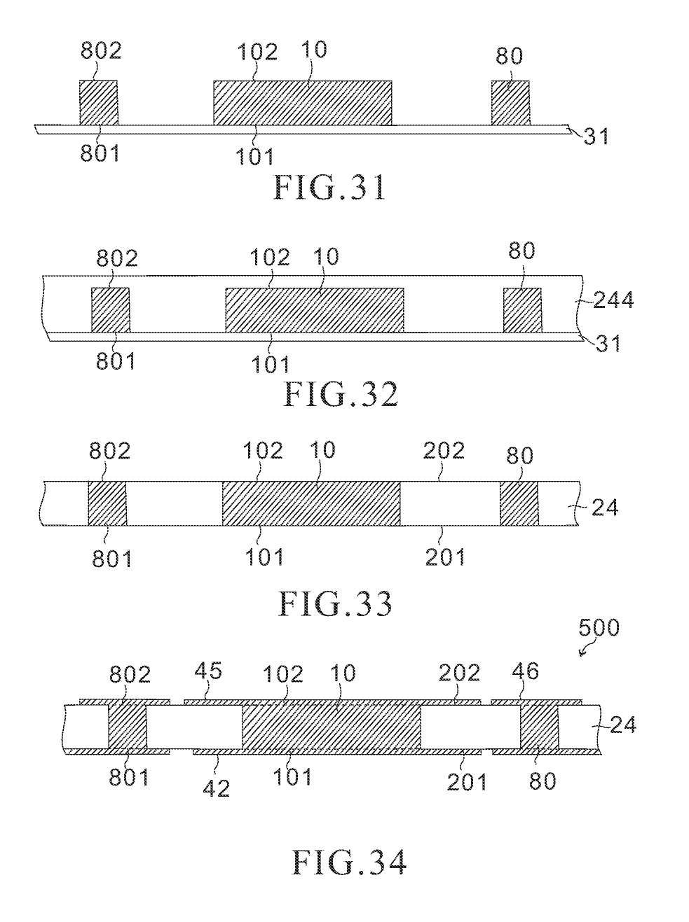

FIGS. 31-34 are schematic views showing another method of making a thermally enhanced wiring board with a plastic embedding compound laterally covering sidewalls of a metal slug and metal posts in accordance with another embodiment of the present invention.

For purposes of brevity, any description in the aforementioned Embodiments is incorporated herein insofar as the same is applicable, and the same description need not be repeated.

FIG. 31 is a cross-sectional view of the structure with the metal slug 10 of FIG. 1 and metal posts 80 on a carrier film 31. The metal slug 10 and the metal posts 80 are attached on the carrier film 31 with their first sides 101, 801 in contact with the carrier film 31.

FIG. 32 is a cross-sectional view of the structure provided with a plastic embedding compound 244. The plastic embedding compound 244 covers the metal slug 10 and the metal posts 80 from above, and laterally covers and surrounds and conformally coats the sidewalls of the metal slug 10 and the metal posts 80.

FIG. 33 is a cross-sectional view of the structure after removal of the carrier film 31 and the upper portion of the plastic embedding compound 244. The plastic embedding compound 244 is ground until the top surface of the plastic embedding compound 244 is substantially coplanar with the second side 102 of the metal slug 10 and the second sides 802 of the metal posts 80. As a result, the metal slug 10 and the metal posts 80 are incorporated with a resin core 24 that has opposite first and second sides 201, 202 essentially coplanar with the first and second sides 101, 102, 801, 802 of the metal slug 10 and the metal posts 80, respectively.

FIG. 34 is a cross-sectional view of the structure provided with first and second moisture inhibiting caps 42, 45 and conductive traces 46. The first and second moisture inhibiting caps 42, 45 and conductive traces 46 can be deposited by a sputtering process and then an electrolytic plating process to achieve desired thickness. Once the desired thickness is achieved, a metal patterning process is executed to form the first and second moisture inhibiting cap 42, 45 and the conductive traces 46. One of the first moisture inhibiting caps 42 laterally extends from the first side 101 of the metal slug 10 to the first side 201 of the resin core 24 from below, and the others laterally extend from the first side 801 of the metal posts 80 to the first side 201 of the resin core 24 from below. The second moisture inhibiting cap 45 is spaced from the conductive traces 46 and laterally extends from the second side 102 of the metal slug 10 to the second side 202 of the resin core from above. The conductive traces 46 laterally extend from the second side 802 of the metal posts 80 to the second side 202 of the resin core 24 from above.

Accordingly, as shown in FIG. 34, a thermally enhanced wiring board 500 is accomplished and includes a metal slug 10, metal posts 80, a resin core 24, first and second moisture inhibiting caps 42, 45 and conductive traces 46. The resin core 24 covers and surrounds sidewalls of the metal slug 10 and the metal posts 80 and is bonded to the metal slug 10 and the metal posts 80. The first moisture inhibiting caps 42 laterally extend on the resin core 22 and further completely cover interfaces between the metal slug 10 and the plastic embedding compound 244 and between the metal posts 80 and the plastic embedding compound 244 from below. The second moisture inhibiting cap 45 laterally extend on the resin core 22 and further completely covers interfaces between the metal slug 10 and the plastic embedding compound 244 from above. The conductive traces 46 laterally extend on the resin core 24 and further completely cover interfaces between the metal posts 80 and the plastic embedding compound 244 and are electrically connected to the metal posts 80 from above.

As illustrated in the aforementioned embodiments, a distinctive thermally enhanced wiring board is configured to have moisture inhibiting caps and exhibit improved reliability. Preferably, the thermally enhanced wiring board includes a metal slug, a resin core, a first moisture inhibiting cap, an optional second moisture inhibiting cap, and conductive traces, wherein (i) the metal slug has planar first and second sides in opposite first and second directions, respectively; (ii) the resin core covers and surrounds sidewalls of the metal slug and has a first side in the first direction and an opposite second side in the second direction; (iii) the first and optional second moisture inhibiting caps laterally extend from the metal slug to the resin core and completely cover interfaces between metal and plastic in the first and second directions, respectively; and (iv) the conductive traces laterally extend on the second side of the resin core.

Optionally, the thermally enhanced wiring board may further include metal posts, wherein (i) the metal posts each have planar first and second sides in the first and second directions, respectively; (ii) the resin core also covers and surrounds sidewalls of the metal posts; and (iii) the conductive traces are electrically connected to the metal posts.

The metal slug can provide primary heat conduction for a semiconductor device to be mounted thereon, whereas the optional metal posts can provide vertical electrical connections between two opposite sides of the wiring board. Accordingly, the heat generated by the semiconductor device can be conducted away through the metal slug, and the optional metal posts can serve as signal vertical transduction pathway or provide ground/power plane for power delivery and return.

The resin core can be bonded to the metal slug and the optional metal posts by a lamination process. For instance, the metal slug and the optional metal posts can be respectively inserted into first and second apertures of a stacking structure having a binding film disposed between a first metal layer and a second metal layer, followed by applying heat and pressure in a lamination process to cure the binding film. By the lamination process, the binding film can provide a secure robust mechanical bond between the first metal layer and the second metal layer, and an adhesive squeezed out from the binding film covers and surrounds and conformally coats sidewalls of the metal slug and the optional metal posts. As a result, a resin core is formed to have opposite first and second sides respectively bonded to the first and second metal layers (typically copper layers), and is adhered to the sidewalls of the metal slug and the optional metal posts by the squeezed out adhesive between the metal slug and the resin core and between the optional metal posts and the resin core. Preferably, the adhesive has a first surface substantially coplanar with the first sides of the metal slug and the optional metal posts and the outer surface of the first metal layer on the resin core in the first vertical direction, and an opposite second surface substantially coplanar with the second sides of the metal slug and the optional metal posts and the outer surface of the second metal layer on the resin core in the second vertical direction.

As another aspect of the present invention, the resin core may be formed by a molding process or other methods such as lamination of epoxy or polyimide to deposit a plastic embedding compound that surrounds and conformally coats and contacts sidewalls of the metal slug and the optional metal posts. Further, a metal plate may be bonded to one side of the resin core by the above molding process or resin lamination process. For instance, the metal slug and the optional metal posts may be partially inserted into openings of a metal plate, followed by depositing the plastic embedding compound that covers the metal plate and the sidewalls of the metal slug and the optional metal posts and extends into gaps between the metal slug and the metal plate and between the optional metal posts and the metal plate. As a result, the resin core can have a first side bonded to the metal plate and an opposite second side substantially coplanar with the second sides of the metal slug and the optional metal posts. Preferably, the metal plate is substantially coplanar with the plastic embedding compound, the metal slug and the optional metal posts in the first direction.

Before the aforementioned lamination or molding process, a carrier film (typically an adhesive tape) may be used to provide temporary retention force. For instance, the carrier film can temporally adhere to the first or second sides of the metal slug and the optional metal posts and the outer surface of the first or second metal layer of the stacking structure to retain the metal slug and the optional metal posts within the first and second apertures of the stacking structure, respectively, followed by the lamination process of the stacking structure. As for the molding case, the carrier film can adhere to the metal slug, the optional metal posts and the optional metal plate, followed by depositing the plastic embedding compound that covers the carrier film, and the optional metal plate, and the sidewalls of the metal slug and the optional metal posts. After the metal slug and the optional metal posts are bonded with the resin core as mentioned above, the carrier film is detached therefrom before depositing the moisture inhibiting cap/the conductive traces.

The first and optional second moisture inhibiting caps can be metal layers (typically copper layers) and completely cover interfaces between two mismatched CTE materials in the first and second directions, respectively. In accordance with the aspect of the resin core bonded to the metal slug by the lamination of the stacking structure, the first and optional second moisture inhibiting caps can contact and completely cover the adhesive between the metal slug and the resin core and interfaces between the metal slug and the adhesive in the first and second directions and further laterally extend on the first and second sides of the resin core, respectively. In this aspect, the first and optional second moisture inhibiting caps can be formed by electroless plating followed by electrolytic plating to deposit plated layers on the first and second surfaces of the adhesive, the first and second sides of the metal slug, and the outer surfaces of the first and second metal layers on the resin core, respectively. As a result, the first moisture inhibiting cap can include a selected portion that laterally extends from the first side of the metal slug to the first metal layer on the resin core, whereas the optional second moisture inhibiting cap can include a selected portion that laterally extends from the second side of the metal slug to the second metal layer on the resin core. More specifically, the first and optional second moisture inhibiting caps include the first and second metal layers of the stacking structure, respectively, and each have a first thickness (equal to the thickness of the plated layer in about 0.5 to 50 microns) where it contacts the adhesive, a second thickness (equal to the combined thickness of the plated layer and the first or second metal layer) where it contacts the resin core that is larger than the first thickness, and a flat surface that faces in the first or second direction, respectively. In accordance with another aspect of the resin core bonded to the metal slug by depositing the plastic embedding compound, the first and optional second moisture inhibiting caps can be formed by thin film sputtering followed by electrolytic plating to deposit plated layers on the first and second sides of the metal slug and the plastic embedding compound. In this aspect, the first and optional second moisture inhibiting caps can laterally extend on the first and second sides of the resin core, and completely cover interfaces between the metal slug and the plastic embedding compound in the first and second directions, respectively, and each have a thickness of about 0.5 to 50 microns. As mentioned above, the first side of the resin core may be bonded with a metal plate, and thus the first moisture inhibiting cap may have a non-uniform thickness. More specifically, the first moisture inhibiting cap may have a first thickness (equal to the thickness of the plated layer in about 0.5 to 50 microns) where it is adjacent to the interfaces between the metal slug and the plastic embedding compound and a second thickness (equal to the combined thickness of the plated layer and the metal plate) that is larger than the first thickness. Likewise, for the wiring board with metal posts as vertical electrical connections, it is preferred to form additional first moisture inhibiting caps each having a selected portion that laterally extends from the first side of the meta post to the first metal layer of the stacking structure, or laterally extends from the first side of the metal post to the first side of the plastic embedding compound. Accordingly, the wiring board can include plural first moisture inhibiting caps spaced from each other to completely cover CTE mismatched interfaces in the first direction. More specifically, in the aspect of the resin core bonded to the metal slug and the metal posts by the lamination of the stacking structure, the additional first moisture caps can contact and completely cover the adhesive between the metal posts and the resin core and interfaces between the metal posts and the adhesive in the first direction and further laterally extend on the first side of the resin core. As for another aspect of the resin core bonded to the metal slug and the metal posts by depositing the plastic embedding compound, the additional first moisture inhibiting caps can laterally extend on the first side of the resin core and completely cover interfaces between the metal posts and the plastic embedding compound in the first direction. Other details regarding the additional first moisture inhibiting caps are the same as those previously described for the first moisture inhibiting cap, and are not repeated for purposes of clarity.

The conductive traces can be formed by a metal patterning process after the deposition process of the plated layer mentioned in the formation of the first and second moisture inhibiting caps. The conductive traces are spaced from the optional second moisture inhibiting cap and can provide electrical contacts for semiconductor device connection. Further, in the wiring board with the metal posts as vertical electrical connections, the conductive traces have selected portions that laterally extend from the second side of the metal posts to the second metal layer of the stacking structure or laterally extend from the second side of the metal posts to the second side of the plastic embedding compound. As a result, the conductive traces can be electrically connected to the metal posts and also completely cover CTE mismatched interfaces near the metal posts in the second direction. More specifically, for the aspect of the metal slug and the metal posts bonded to the resin core by the lamination of the stacking structure, the conductive traces completely cover the adhesive between the metal posts and the resin core and interfaces between the metal posts and the adhesive in the second direction. In this aspect, the conductive traces can have a first thickness (equal to the thickness of the plated layer in about 0.5 to 50 microns) where they contact the adhesive and a second thickness (equal to the combined thickness of the plated layer and the second metal layer) where they contact the resin core that is larger than the first thickness. As for another aspect of the resin core bonded to the metal slug and the metal posts by depositing the plastic embedding compound, the conductive traces completely cover interfaces between the metal posts and the plastic embedding compound in the second direction.

The present invention also provides a semiconductor assembly in which a semiconductor device such as chip is mounted over the second side of the metal slug of the aforementioned wiring board and is electrically connected to the conductive traces of the wiring board by, for example, bonding wires. Further, a lid can be provided to enclose the semiconductor device therein. Accordingly, even if cracks are generated at the interfaces between two mismatched CTE materials, the moisture inhibiting cap of the wiring board can restrict the passage of moisture through the cracks from ambiance into the interior of the semiconductor assembly. Further, the heat generated by the semiconductor device can be transferred to the metal slug and further spread out to the moisture inhibiting cap that has a larger thermal dissipation surface area than the metal slug.

The assembly can be a first-level or second-level single-chip or multi-chip device. For instance, the assembly can be a first-level package that contains a single chip or multiple chips. Alternatively, the assembly can be a second-level module that contains a single package or multiple packages, and each package can contain a single chip or multiple chips. The chip can be a packaged or unpackaged chip. Furthermore, the chip can be a bare chip, or a wafer level packaged die, etc.

The term “cover” refers to incomplete or complete coverage in a vertical and/or lateral direction. For instance, in the position that the first moisture inhibiting cap faces the downward direction, the semiconductor device covers the metal slug in the upward direction regardless of whether another element such as the second moisture inhibiting cap is between the semiconductor device and the second moisture inhibiting cap.

The phrases “mounted on” and “attached on” include contact and non-contact with a single or multiple support element(s). For instance, the semiconductor device can be attached on the second moisture inhibiting cap regardless of whether it contacts the second moisture inhibiting cap or is separated from the second moisture inhibiting cap by an adhesive.

The phrases “electrical connection” and “electrically connected” refer to direct and indirect electrical connection. For instance, the semiconductor device is electrically connected to the conductive traces by the bonding wires but does not contact the conductive traces.

The “first direction” and “second direction” do not depend on the orientation of the wiring board, as will be readily apparent to those skilled in the art. For instance, the first side of the metal slug faces the first direction and the second side of the metal slug faces the second direction regardless of whether the wiring board is inverted. Thus, the first and second directions are opposite one another and orthogonal to the lateral directions, and a lateral plane orthogonal to the first and second directions intersects laterally aligned elements. Furthermore, the first direction is the downward direction and the second direction is the upward direction in the position that the first moisture inhibiting cap faces the downward direction, and the first direction is the upward direction and the second direction is the downward direction in the position that the first moisture inhibiting cap faces the upward direction.

The thermally enhanced wiring board according to the present invention has numerous advantages. The metal slug provides a heat dissipation pathway from the chip to the first moisture inhibiting cap underneath the metal slug. The resin core provides mechanical support and serves as a spacer between the conductive traces and the metal slug and the metal posts and the metal slug. The first moisture inhibiting cap seals interfaces between metal and a surrounding plastic material and restricts the passage of moisture though cracks at the interfaces. The conductive traces provide horizontal electrical routing of the board, whereas the metal posts provide vertical electrical routing of the board. The wiring board made by this method is reliable, inexpensive and well-suited for high volume manufacture.

The manufacturing process is highly versatile and permits a wide variety of mature electrical and mechanical connection technologies to be used in a unique and improved manner. The manufacturing process can also be performed without expensive tooling. As a result, the manufacturing process significantly enhances throughput, yield, performance and cost effectiveness compared to conventional techniques.

The embodiments described herein are exemplary and may simplify or omit elements or steps well-known to those skilled in the art to prevent obscuring the present invention. Likewise, the drawings may omit duplicative or unnecessary elements and reference labels to improve clarity.

What is claimed is:

1. A method of making a thermally enhanced wiring board having metal slug and moisture inhibiting cap incorporated therein, comprising steps of:
providing a metal slug having planar first and second sides in opposite first and second directions, respectively;
providing a stacking structure that includes first and second metal layers, a binding film disposed between the first and second metal layers, and a first aperture extending through the first metal layer, the binding film and the second metal layer, wherein the first and second metal layers each have a planar outer surface in the first and second directions, respectively;
inserting the metal slug into the first aperture of the stacking structure leaving a gap between the stacking structure and the metal slug, and then curing the binding film to form a resin core that has a first side bonded to the first metal layer and an opposite second side bonded to the second metal layer, wherein the stacking structure is adhered to sidewalls of the metal slug by an adhesive squeezed out from the binding film into the gap between the stacking structure and the metal slug;
removing an excess portion of the squeezed out adhesive, thereby the adhesive having opposite exposed surfaces substantially coplanar with the first and second sides of the metal slug and the outer surfaces of the first and second metal layers in the first and second directions;
forming conductive traces that laterally extend on the second side of the resin core; and
forming a first moisture inhibiting cap that laterally extends from the first side of the metal slug to the first metal layer to completely cover the exposed surface of the adhesive from the first direction.

2. The method of claim 1, wherein a second moisture inhibiting cap is simultaneously formed by the step of forming the conductive traces and laterally extends from the second side of the metal slug to the second metal layer on the resin core to completely cover the exposed adhesive from the second direction.

3. The method of claim 1, further comprising a step of providing metal posts each having planar first and second sides in the first and second directions, respectively, wherein (i) the stacking structure further includes second apertures extending through the first metal layer, the binding film and the second metal layer, (ii) the step of inserting the metal slug into the first aperture includes inserting the metal posts into the second apertures of the stacking structure, therewith the adhesive also being squeezed into gaps between the stacking structure and the metal posts, and (iii) the conductive traces are electrically connected to the metal posts.

4. The method of claim 2, wherein the first and second moisture inhibiting caps are metal layers formed by electroless plating followed by electrolytic plating and each has a thickness between 0.5 micron and 50 microns where it contacts the squeezed out adhesive.

5. A method of making a thermally enhanced wiring board having metal slug and moisture inhibiting cap incorporated therein, comprising steps of:
attaching a metal slug on a carrier film, wherein the metal slug has planar first and second sides in opposite first and second directions, respectively;
depositing a plastic embedding compound that covers the metal slug and the carrier film;
removing a portion of the plastic embedding compound to form a resin core that has a first side in the first direction and a second side substantially coplanar with the second side of the metal slug in the second direction, and detaching the carrier film therefrom;
forming conductive traces that laterally extend on the second side of the resin core; and
forming a first moisture inhibiting cap that completely covers interfaces between the metal slug and the resin core from the first direction.

6. The method of claim 5, wherein a second moisture inhibiting cap is simultaneously formed by the step of forming the conductive traces and completely covers interfaces between the metal slug and the resin core from the second direction.

7. The method of claim 5, further comprising a step of attaching metal posts on the carrier film, the metal posts each having planar first and second sides in the first and second directions, respectively, wherein (i) the second side of the resin core is also substantially coplanar with the second side of the metal posts in the second direction after the step of removing a portion of the plastic embedding compound, and (ii) the conductive traces are electrically connected to the metal posts.

8. The method of claim 6, wherein the first and second moisture inhibiting caps are metal layers formed by thin film sputtering followed by electrolytic plating and each has a thickness between 0.5 micron and 50 microns where it is adjacent to the interfaces between the metal slug and the plastic embedding compound.

9. A semiconductor assembly, comprising:
a thermally enhanced wiring board, including:
a metal slug that has planar first and second sides in opposite first and second directions, respectively;
a resin core that covers and surrounds sidewalls of the metal slug and has a first side in the first direction and an opposite second side in the second direction;
an adhesive that is sandwiched between the metal slug and the resin core;
a first moisture inhibiting cap that completely covers the adhesive in the first direction, wherein the first moisture inhibiting cap has a first thickness where it contacts the adhesive and a second thickness where it contacts the resin core that is larger than the first thickness; and
conductive traces that laterally extend on the second side of the resin core; and
a semiconductor device that is mounted over the second side of the metal slug and is electrically connected to the conductive traces.

10. The semiconductor assembly of claim 9, wherein the thermally enhanced wiring board further includes a second moisture inhibiting cap that completely covers the adhesive from the second direction.

11. The semiconductor assembly of claim 9, wherein (i) the thermally enhanced wiring board further includes metal posts each having planar first and second sides in the first and second directions, respectively, (ii) the resin core also covers and surrounds sidewalls of the metal posts, (iii) the adhesive is also sandwiched between the metal posts and the resin core, and (iv) the conductive traces are electrically connected to the metal posts.

12. The semiconductor assembly of claim 10, wherein the first and second moisture inhibiting caps are metal layers and each has a thickness between 0.5 micron and 50 microns where it contacts the adhesive.
